(19) United States
(12) Patent Application Publication
(10) Pub. No.: US 2026/0251848 A1
(43) Pub. Date: Aug. 27, 2026

(54) BONDING STRUCTURE, PHOTONIC INTEGRATED CIRCUIT, AND METHOD FOR ACTIVE ALIGNMENT OF OPTICAL AXIS OF SEMICONDUCTOR OPTICAL DEVICE WITH OPTICAL AXIS OF OPTICAL CIRCUIT ON SUBSTRATE

(71) Applicant: Teknologian tutkimuskeskus VTT Oy, Espoo (FI)

(72) Inventors: Jae-Wung LEE, Espoo (FI); Mikko HARJANNE, Espoo (FI); Tomi HASSINEN, Espoo (FI); Timo AALTO, Espoo (FI); Giovanni DELROSSO, Espoo (FI)

(21) Appl. No.: 18/879,370

(22) PCT Filed: May 31, 2023
(86) PCT No.: PCT/FI2023/050304

§ 371 Date: Dec. 27, 2024

(30) Foreign Application Priority Data
Jun. 29, 2022 (FI) 20225594

(51) Int. Cl. G02B 6/13

(52) U.S. Cl. CPC G02B 6/13

(57) ABSTRACT

A bonding structure (100) and a method for active alignment of an optical axis (OAX1) of a semiconductor optical device (20) with an optical axis (OAX2) of an optical circuit (30) on a substrate (10), and a photonic integrated circuit (110). The bonding structure (100) comprises at least one first bonding member (11) on the substrate (10) for first bonding the semiconductor optical device (20) to the substrate (10), wherein the first bonding member (11) is made of material, such as porous metal, exhibiting plastic deformation to allow deforming of the at least one first bonding member (11) during the active alignment. Furthermore, the bonding structure (100) comprises at least one second bonding member (12) on the substrate (10) for second bonding the semiconductor optical device (20) to the substrate (10) upon completion or after the active alignment.

### FIELD OF THE INVENTION

The present invention relates in general to photonics devices and more specifically to bonding structures for bonding a semiconductor optical device onto a substrate. In particular, however not exclusively, the present invention concerns a bonding structure for active alignment of an optical axis of a semiconductor optical device with an optical axis of an optical circuit on the substrate.

### BACKGROUND

In known photonics devices, the optical circuit is design and adapted so that when a semiconductor optical device is placed, such as bonded, to the substrate having the optical circuit, the optical axes thereof are meant to be aligned with each other. In the ideal case, the alignment of the axes would be proper as designed. However, in practice, this is always not the case.

There may be, for example, differences between the real spot and the expected spot where laser is coming out of the semiconductor optical device which then causes misalignment with the optical axis of the optical circuit. On the other hand, there can be bonding errors, for example, due to particles, squeezing of bonding material, or slip, etc. Furthermore, defects on facet, for example, because of tilting due to a process issue or the effect of the thickness of an anti-reflective coating. Still further, there may be other process or design errors, such as during or in the fabrication or bonding. Thus, there are many factors which can cause misalignment of the optical axes in practical application, even if the device would be carefully designed so that the alignment should be correct after the bonding of components onto the substrate.

### SUMMARY

An objective of the present invention is to provide a bonding structure for active alignment of an optical axis of a semiconductor optical device with an optical axis of an optical circuit on a substrate, a photonic integrated circuit, and a method for active alignment of an optical axis of a semiconductor optical device with an optical axis of an optical circuit on a substrate. Another objective of the present invention is that the bonding structure, the photonic integrated circuit, and the method improves the alignment of the optical axes between the semiconductor optical device and the optical circuit with which the device is designed to operate.

The objectives of the invention are reached by a bonding structure for active alignment of an optical axis of a semiconductor optical device with an optical axis of an optical circuit on a substrate, a photonic integrated circuit, and a method for active alignment of an optical axis of a semiconductor optical device with an optical axis of an optical circuit on a substrate as defined by the respective independent claims.

According to a first aspect, a bonding structure for active alignment of an optical axis of a semiconductor optical device with an optical axis of an optical circuit on a substrate is provided. The bonding structure comprises at least one first bonding member on the substrate for first bonding of the semiconductor optical device to the substrate. The first bonding member is made of material exhibiting plastic deformation to allow deforming of the at least one first bonding member during the active alignment, the material being porous metal. Furthermore, the bonding structure comprises at least one second bonding member on the substrate for bonding the semiconductor optical device to the substrate upon completion or after the active alignment. Preferably, the second bonding member(s) may be unbonded relative to the device before the completion of the active alignment, thereby not interfering the alignment process.

The plastic deformation refers herein to ability of the first bonding member(s) of a solid material to undergo permanent deformation, a non-reversible change of shape in response to applied force. Thus, the first bonding member(s) do not return to their previous shape, at least in any significant amount, after the force has been removed.

The porous metal may be selected from the group consisting of: porous copper, porous aluminum, porous gold.

The at least one second bonding member may be of solder material or eutectic bonding material.

In some embodiments, the at least one second bonding member may be arranged relative to the first bonding member so that upon melting of the second bonding member, material of the second bonding member penetrates the porous metal of the at least one first bonding member, thereby forming an intermetallic compound. Furthermore, the at least one second bonding member may be arranged adjacent to the first bonding member on the substrate.

The first bonding member(s) is/are porous at least during the active alignment and before the second bonding.

Alternatively or in addition, an opposite end of the at least one first bonding member relative to the substrate may extend beyond an opposite end of the at least one second bonding member relative to the substrate. Thus, the semiconductor optical device, when being arranged in contact with the bonding structure, becomes first in contact with the at least one first bonding member.

In various embodiments, the at least one second bonding member may be arranged to act as a stopper during or upon completion of the active alignment. Thus, the semiconductor optical device may abut against the at least one second bonding member if being brought enough towards the substrate during the alignment.

The bonding structure may comprise a plurality of first bonding members. The plurality of first bonding members may be arranged on opposite or different sides of the at least one second bonding member on the substrate. In some embodiments, there may be four first bonding members arranged so that they become in contact, for example, with four corner portions of the semiconductor optical device.

The at least one first bonding member or the plurality of first bonding members may have a longitudinal shape in a direction away from the substrate.

According to a second aspect, a photonic integrated circuit is provided. The photonic integrated circuit comprises an optical circuit, such as of a sensing device, on a substrate, and a semiconductor optical device aligned with the optical circuit and bonded to the substrate by the bonding structure in accordance with the first aspect as described hereinabove.

The semiconductor optical device may be one selected from the group consisting of: a semiconductor optical amplifier, a photodiode, a laser diode.

According to a third aspect, a method for active alignment of an optical axis of a semi-conductor optical device with an optical axis of an optical circuit on a substrate is provided. The method comprises
providing at least one first bonding member on the substrate for first, or initial, bonding the semiconductor optical device to the substrate, wherein the first bonding member is made of material exhibiting plastic deformation to allow deforming of the at least one first bonding member, the material being porous metal,
providing at least one second bonding member on the substrate for second, or final, bonding the semiconductor optical device to the substrate,
bonding the semiconductor optical device to the at least one first bonding member,
aligning the optical axis of the semiconductor optical device with the optical axis of the optical circuit by applying force to the semiconductor optical device to deform the at least one first bonding member, and
bonding the aligned semiconductor optical device by the at least one second bonding member.

Furthermore, the aligning may comprise applying the force by a flip-chip bonder head or arm holding the semiconductor optical device during the active alignment.

Still further, the method may comprise melting the at least one second bonding member in a reflow soldering process.

The present invention provides a bonding structure, a photonic integrated circuit, and a method for active alignment of an optical axis of a semiconductor optical device with an optical axis of an optical circuit on a substrate. The present invention provides advantages over known solutions in that a reliable bonding of components with good optical alignment is achieved. The optical alignment can be actively controlled by the use of the bonding structure so as to obtain proper alignment between the optical axes.

Various other advantages will become clear to a skilled person based on the following detailed description.

The expression “a plurality of” may refer to any positive integer starting from two (2), that is, being at least two, two, at least three, three, etc.

The terms “first”, “second” and “third” are herein used to distinguish one element from other element, and not to specially prioritize or order them, if not otherwise explicitly stated.

The exemplary embodiments of the present invention presented herein are not to be interpreted to pose limitations to the applicability of the appended claims. The verb “to comprise” is used herein as an open limitation that does not exclude the existence of also unrecited features. The features recited in dependent claims are mutually freely combinable unless otherwise explicitly stated.

The novel features which are considered as characteristic of the present invention are set forth in particular in the appended claims. The present invention itself, however, both as to its construction and its method of operation, together with additional objectives and advantages thereof, will be best understood from the following description of specific embodiments when read in connection with the accompanying drawings.

### BRIEF DESCRIPTION OF FIGURES

Some embodiments of the invention are illustrated by way of example, and not by way of limitation, in the figures of the accompanying drawings.

FIG. 1 illustrates schematically a bonding structure.

FIGS. 2A-2D illustrate schematically some stages of aligning and bonding a semiconductor optical device with an optical circuit on a substrate using a bonding structure.

FIGS. 3A and 3B illustrate schematically examples of the alignment of an optical axis of a semiconductor optical device with that of an optical circuit on a substrate.

FIG. 4 Illustrates Schematically a Bonding Structure.

FIGS. 5A-5C illustrate schematically some stages of aligning and bonding a semiconductor optical device with an optical circuit on a substrate using a bonding structure.

FIG. 6 illustrate schematically a flip-chip bonding device or arm utilizable in aligning an optical axis of a semiconductor optical device with that of an optical circuit on a substrate.

FIG. 7 illustrates schematically a photonic integrated circuit as viewed from above.

FIG. 8 shows a flow diagram of a method.

### DETAILED DESCRIPTION OF SOME EMBODIMENTS

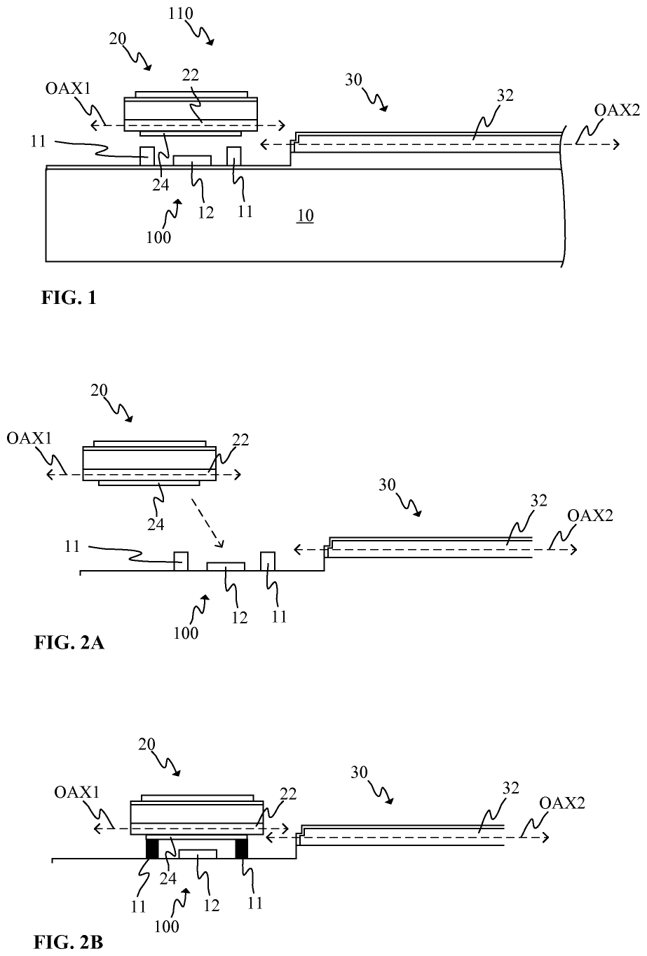

FIG. 1 illustrates schematically a bonding structure 100. Also, a semiconductor optical device 20 and a portion of an optical circuit 30 on a substrate 10, such as silicon photonics platform, are illustrated. The bonding structure 100 in FIG. 1 comprises at least one first bonding member 11 on the substrate 10 for first, or initial, bonding the semiconductor optical device 20 to the substrate 10, wherein the first bonding member 11 is made of material exhibiting plastic deformation to allow deforming of the at least one first bonding member 11 during the active alignment. Furthermore, the bonding structure 100 comprises at least one second bonding member 12 on the substrate 10 for second, or final, bonding the semiconductor optical device 20 to the substrate 10 upon completion or after the active alignment. Preferably, the at least one second bonding member 12 may be arranged adjacent to the first bonding member(s) 11 on the substrate 10.

Furthermore, an opposite end of the at least one first bonding member 11 relative to the substrate 10, preferably, extends beyond an opposite end of the at least one second bonding member 12 relative to the substrate 10. Thus, the semiconductor optical device 20 becomes first in contact with the at least one first bonding member 11 when the device 20 is arranged towards the substrate 10 to be bonded before becoming in contact with the second bonding member(s) 12.

The second bonding member(s) 12 may be arranged to act as a stopper during or upon completion of the active alignment. Thus, the movement of the semiconductor optical device 20 may be limited to certain position by the second bonding member(s) 12. The certain position is, preferably, a position in which the alignment is sufficiently good, if not optimal.

As can be seen, the semiconductor optical device 20 defines an optical axis OAX1, that is a first optical axis, which is the direction into which the optical signal, such as light or laser, exits the device 20. On the other hand, the optical circuit 30 also defines an optical axis OAX2, that is a second optical axis, which is related to the positioning/orientation of the waveguide of the optical circuit 30. To properly function, the optical axis OAX1 of the semiconductor optical device 20 and the optical axis OAX2 of the optical circuit 30 must be so positioned, or aligned, with respect to each other so that the optical signal provided by the semiconductor optical device 20 can enter the optical circuit 30 efficiently enough to be transmitted further on. Thus, the alignment of the axes OAX1, OAX2 relates most importantly to the alignment of the exit point and entry point of the optical signal from the semiconductor optical device 20 and to the optical circuit 30, respectively.

Regarding the semiconductor optical device 20, which may be a semiconductor optical amplifier, a photodiode, or a laser diode, it may comprise an active layer 22 from which the optical signal is being outputted. The semiconductor optical device 20 may also comprise a first contact layer 24, or a bottom contact layer or electrode, by which the device 20 is to be connected, such as bonded, to the substrate 10. As known to a person skilled in the art, the semiconductor optical device 20 may also comprise other layers, such as a second contact layer (such as a top contact layer or electrode on the top of the device 20 of FIG. 1), as well as antireflective layer(s) and cladding layers.

Regarding the optical circuit 30, it may comprise a waveguide 32, such as a silicon waveguide, for transmitting optical signal therein. As shown in FIG. 1, the optical circuit 30 may be part of a photonic integrated circuit 110, such as of a silicon photonic device.

In FIG. 1, there are shown two first bonding members 11, however, there may be only one or more than two, such as four. The first bonding member(s) 11 may, preferably, be made of electrically conductive material, such as of electrically conductive metal. Although not shown in FIG. 1, the first bonding member(s) 11 may be provided onto a specific contact pad(s) or area(s) provided on or define by the substrate 10. The contact pad(s) or area(s) may then be further connected to other components or circuit of the device.

In addition, there may be only one second bonding member 12 or several of them. The second bonding member 12 may also be provided onto a specific contact pad(s) or area(s) provided on or define by the substrate 10. The contact pad(s) or area(s) may be the same or different than the ones utilized for the first bonding member(s) 11.

In various embodiments, the material of the first bonding member(s) 11 is substantially or at least comprises mostly of the same material than the first contact layer 24 of the semiconductor optical device 20.

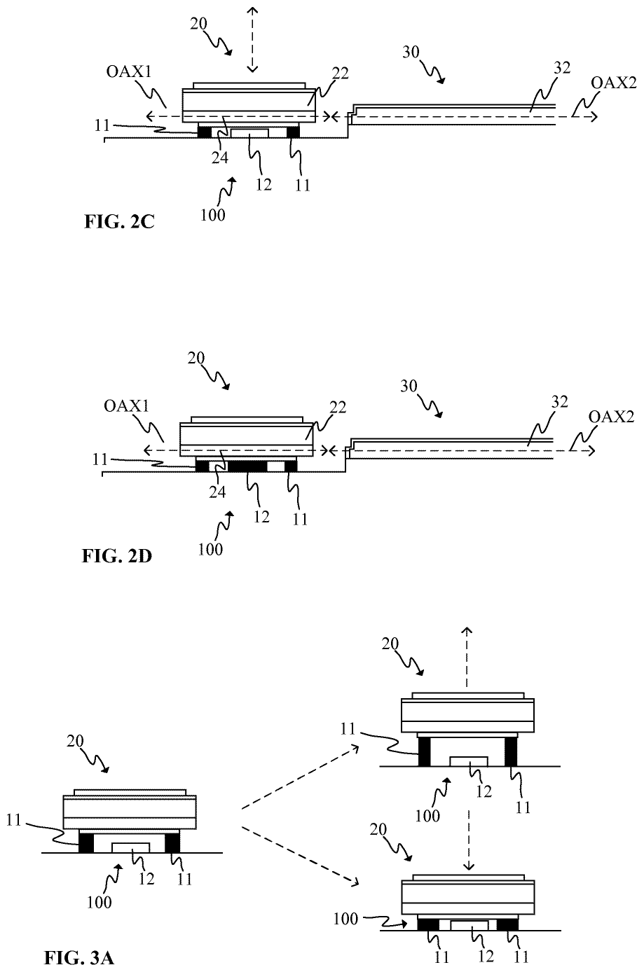

FIGS. 2A-2D illustrate schematically some stages of aligning and bonding a semiconductor optical device 20 with an optical circuit 30 on a substrate 10 using a bonding structure 100. As visible in FIGS. 2A-2D, said components/elements may be substantially similar to the ones illustrated in and described in connection to FIG. 1.

FIG. 2A illustrates the semiconductor optical device 20 between brought into the vicinity of the substrate 10 and towards the bonding structure 100 thereon.

FIG. 2B illustrates the semiconductor optical device 20 being first, or initially, bonded to the first bonding members 11, for example, by using an elevated temperature to at least partially melt the first bonding members 11 and/or the first contact layer 24, thereby bonding them to each other. Other bonding techniques may alternatively be used. In FIG. 2B, the first bonding members 11 are shown with black fill color to indicate that they are bonded to the device 20.

FIG. 2C illustrates the semiconductor optical device 20 being moved in the vertical direction to align the optical axes OAX1, OAX2. During the alignment, in this movement in the vertical direction, the first bonding members 11, which are made of material exhibiting plastic deformation, deform due to the force utilized to move the semiconductor optical device 20. Once a sufficiently good alignment has been obtained, the alignment is completed. This may entail having the axes OAX1, OAX2 at a distance from each other which is less than a distance threshold or the optical signal may be measured to be sufficiently coupled to the optical circuit 30 so that, for example, the silicon photonic device can function properly.

FIG. 2D illustrates the semiconductor optical device 20 being second, or finally, bonded to the substrate 10 by the at least one second bonding member 12. In this case too, the second bonding member 12 is shown with black fill color to indicate that the bonding has been performed. The bonding by the second bonding member(s) 12, such as by solder or eutectic bonding material, is, preferably, designed to provide even better bonding to the substrate 10 than the first bonding so that the semiconductor optical device 20 is not easily movable later on. The second bonding member 12 is thus, preferably, not exhibiting plastic deformation but material/composition which provide more rigid bonding is utilized, such as utilizing typical solder or eutectic bonding materials. For example, tin or tin lead type materials may be utilized for the second bonding member 12. In a way, the second bonding then fixes the semiconductor optical device 20 to its aligned position.

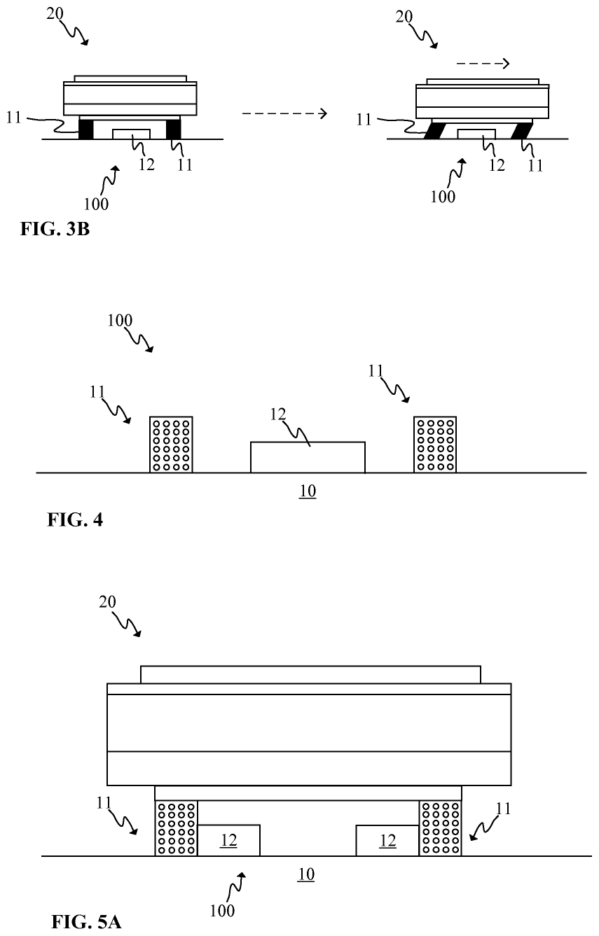

FIGS. 3A and 3B illustrate schematically examples of the alignment of an optical axis OAX1 of a semiconductor optical device 20 with that of an optical circuit 30 on a substrate 10. In FIG. 3A, the semiconductor optical device 20 is being moved in a vertical direction, up and/or down. In FIG. 3A, it is shown, or in fact exaggerated, that the width of the first bonding members 11 may alter during the movement. For example, when stretching the first bonding members 11 to be longer, the width of them may reduce such as shown on right in the top portion of the figure. On the hand, when compressing the first bonding members 11 against the substrate 10 to be shorter, the width of the first bonding members 11 may increase.

In FIG. 3B, the semiconductor optical device 20 is being moved in a horizontal direction, left and/or right. As both ends of the first bonding members 11 are bonded to their corresponding counterparts, the horizontal movement produces inclined or tilted first bonding members 11. The tilting may be utilized to increase or, preferably, decrease a gap between the semiconductor optical device 20 and the optical circuit 30. Alternatively or in addition, the tilting can be utilized to simultaneously move the semiconductor optical device 20 in both the vertical and the horizontal directions, resulting in rotative movement around the coupling point of the first bonding members 11 to the substrate 10. In this case, the width of the first bonding members 11 can be maintained, however, it can also be altered.

FIG. 4 illustrates schematically a bonding structure 100. In the bonding structure 100 of FIG. 4, the material of the first bonding member 11 is porous metal. This is indicated by the small circles within the bonding members 11 which imply porosity of the material. In various embodiments, the porous metal is porous copper, porous aluminum, or porous gold. In this case, the porosity of the first bonding member(s) 11 provides the property of plastic deformation to the first bonding member(s) 11.

In various embodiments, the material of the first contact layer 24 of the semiconductor optical device 20 may be the same as the material of the porous metal of the first bonding member 11, however, preferably not porous. Thus, the material of the first contact layer 24 may (at least mostly) be copper, aluminum, or gold, respectively to the material of the porous metal of the first bonding member(s) 11.

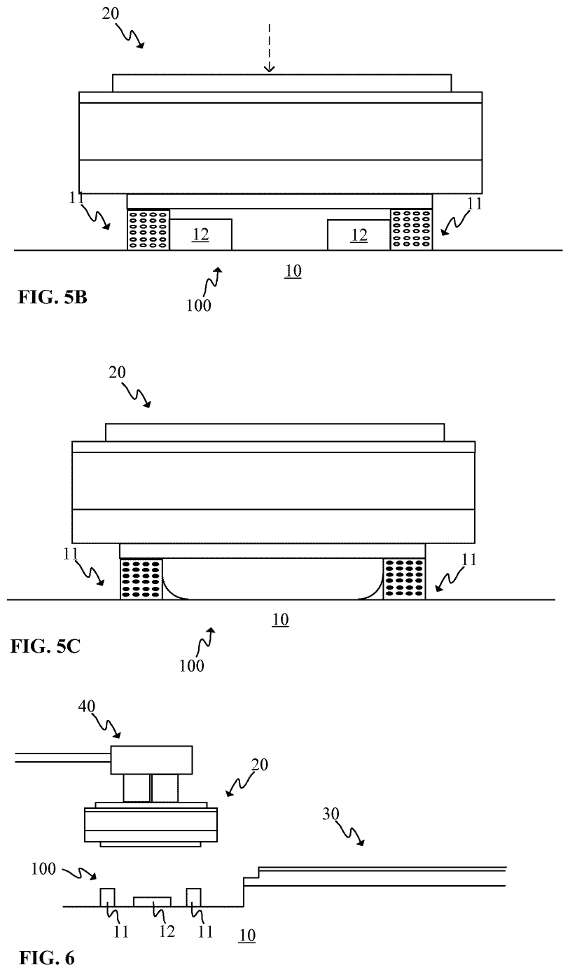

FIGS. 5A-5C illustrate schematically some stages of aligning and bonding a semiconductor optical device 20 with an optical circuit 30 on a substrate 10 using a bonding structure 100. In this case too, the material of the first bonding member(s) 11 is porous metal. As shown in FIG. 5A, the second bonding members 12 (there could alternatively be only one) are arranged adjacent relative to the first bonding member 11. In FIG. 5A, the semiconductor optical device 20 is being bonded with the first bonding members 11. In FIG. 5B, a force is applied to move the semiconductor optical device 20 so that the length of the first bonding members 11 reduces. This is illustrated in FIG. 5B by the ellipses (corresponding to the small circles in FIG. 5A) within the first bonding member 11 and also by the reduced height of the bonding members 11.

FIG. 5C illustrates that the second bonding members 12 are arranged relative to the first bonding member 11 so that upon melting of the second bonding member 12, material of the second bonding members 12 penetrates the porous metal of the corresponding ones of at least one first bonding member 11, respectively, thereby forming an intermetallic compound. This is emphasized in FIG. 5C by the black fill color of the ellipses within the bonding members 11. The penetration of the material of the second bonding member 12 then fixes the semiconductor optical device 20 to its aligned position since the first bonding member 11 becomes at least less, if not completely, non-porous and thereby more rigid. FIG. 5C has small “tails” drawn next to the first bonding member 11 to merely indicate that the material of the second bonding members 12 has penetrated the first bonding member 11. However, in practice, small amount of material may be left out to form such tails.

FIG. 6 illustrate schematically a flip-chip bonding device 40 or arm 40 utilizable in aligning an optical axis OAX1 of a semiconductor optical device 20 with that OAX2 of an optical circuit 30 on a substrate 10. The flip-chip bonding device 40 or arm 40 can be used to produce the force for moving the semiconductor optical device 20 and thus for aligning the optical axes OAX1, OAX2. The flip-chip bonding device 40 or arm 40 can be used to move the semiconductor optical device 20 in vertical and/or horizontal directions, or basically all directions. Thus, the force can have any direction.

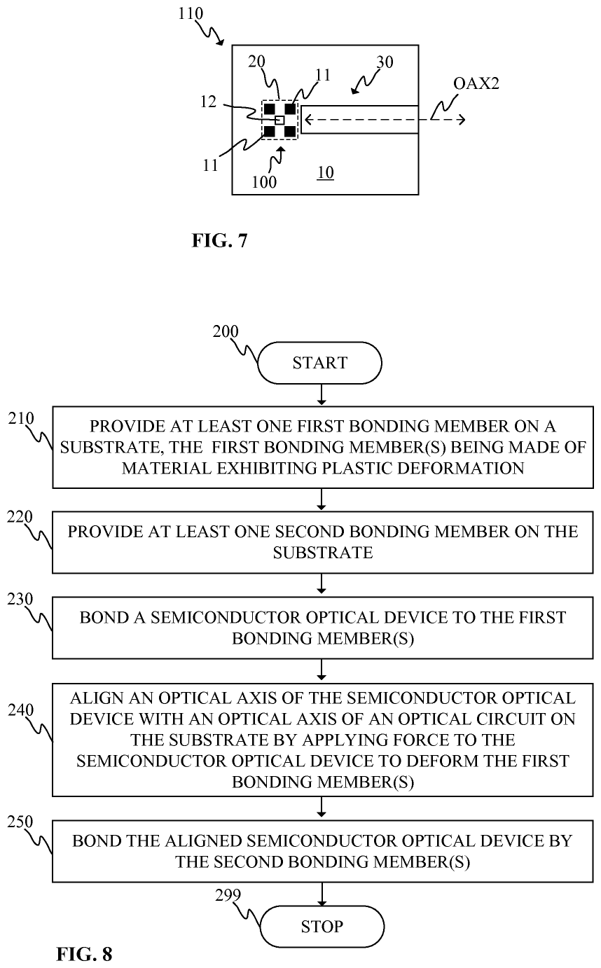

FIG. 7 illustrates schematically a photonic integrated circuit 110 as viewed from above. The photonic integrated circuit 110 comprises the optical circuit 30 and the semiconductor optical device 20 on the substrate 10. Furthermore, the semiconductor optical device 20 has been bonded to the substrate 10 by four first bonding members 11 arranged to corner portions of the semiconductor optical device 20. There is one second bonding portion 12 in the middle of the four first bonding members 11 with which the semiconductor optical device 20 has also been bonded to the substrate 10 after the aligning of the optical axes OAX1, OAX2. The plurality of first bonding members 11 may thus be arranged on opposite sides of the at least one second bonding member 12 on the substrate 10. Optical axis OAX1 has been omitted from FIG. 7 for the sake of legibility. The number of first bonding members 11 and/or the second bonding member 12 could easily be different than in FIG. 7.

FIG. 8 shows a flow diagram of a method. Item (or method step) 210 refers to an optional general start-up phase of the method. Suitable equipment and components are obtained and systems assembled and configured for operation.

Item 210 refers to providing at least one first bonding member 11 on the substrate 10 for first, or initial, bonding the semiconductor optical device 20 to the substrate 10, wherein the first bonding member 11 is, or members 11 are, made of material exhibiting plastic deformation to allow deforming of the at least one first bonding member 11.

Item 220 refers to providing at least one second bonding member 12 on the substrate 10 for second, or final, bonding the semiconductor optical device 120 to the substrate 10. In various embodiments, the order of items 210 and 220 may different or even be performed substantially simultaneously.

Item 230 refers to bonding the semiconductor optical device 20 to the at least one first bonding member 11. This may be performed by utilizing an elevator temperature to at least partly melt the surfaces which are to become in contact with each other during the bonding.

Item 240 refers to aligning the optical axis OAX1 of the semiconductor optical device 20 with the optical axis OAX2 of the optical circuit 30 by applying force to the semi-conductor optical device 20, such as by a flip-chip bonder head or arm, to deform the at least one first bonding member 11.

Item 250 refers to bonding the aligned semiconductor optical device 20 by the at least one second bonding member 12.

In some embodiments, the method may comprise melting the at least one second bonding member 12 in a reflow soldering process. In the reflow soldering process, the second bonding member(s) 12 may then bond and fix the semiconductor optical device 20 in its aligned position. This may be performed as shown in FIG. 2A-2D or 5A-5C.

Method execution may be stopped at item 299.

1. A bonding structure (100) on a substrate (10) for active alignment of an optical axis (OAX1) of a semiconductor optical device (20) with an optical axis (OAX2) of an optical circuit (30) on the substrate (10), wherein the bonding structure (100) comprises:
at least one first bonding member (11) on the substrate (10) for first bonding the semiconductor optical device (20) to the substrate (10), wherein the first bonding member (11) is made of material exhibiting plastic deformation to allow deforming of the at least one first bonding member (11) during the active alignment, wherein the material is porous metal, and
at least one second bonding member (12) on the substrate (10) for second bonding the semiconductor optical device (20) to the substrate (10) upon completion or after the active alignment.

2. The bonding structure (100) of claim 1, wherein the porous metal is selected from the group consisting of: porous copper, porous aluminum, porous gold.

3. The bonding structure (100) of claim 1, wherein the at least one second bonding member (12) is of solder or eutectic bonding material.

4. The bonding structure (100) of claim 1, wherein the at least one second bonding member (12) is arranged relative to the first bonding member (11) so that upon melting of the second bonding member (12), material of the second bonding member penetrates the porous metal of the at least one first bonding member (11), thereby forming an intermetallic compound.

5. The bonding structure (100) of claim 4, wherein the at least one second bonding member (12) is arranged adjacent to the first bonding member (11) on the substrate (10).

6. The bonding structure (100) of claim 1, wherein an opposite end of the at least one first bonding member (11) relative to the substrate (10) extends beyond an opposite end of the at least one second bonding member (12) relative to the substrate (10).

7. The bonding structure (100) of claim 1, wherein the at least one second bonding member (12) is arranged to act as a stopper during or upon completion of the active alignment.

8. The bonding structure (100) of claim 1, comprising a plurality of first bonding members (11) arranged on opposite sides of the at least one second bonding member (12) on the substrate (10).

9. The bonding structure (100) of claim 1, wherein the at least one first bonding member (11) has or the plurality of first bonding members (11) have a longitudinal shape in a direction away from the substrate (10).

10. A photonic integrated circuit (110) comprising:
an optical circuit (30) on a substrate (10), and
a semiconductor optical device (20) aligned with the optical circuit (30) and bonded to the substrate (10) by a bonding structure (100) of any one of claims 1-9.

11. The photonic integrated circuit (110) of claim 10, wherein the semiconductor optical device (20) is one selected from the group consisting of: a semiconductor optical amplifier, a photodiode, a laser diode.

12. A method for active alignment of an optical axis (OAX1) of a semiconductor optical device (20) with an optical axis (OAX2) of an optical circuit (30) on a substrate (10), the method comprising:
providing (210) at least one first bonding member (11) on the substrate (10) for first bonding the semiconductor optical device (20) to the substrate (10), wherein the first bonding member (11) is made of material exhibiting plastic deformation to allow deforming of the at least one first bonding member (11), the material being porous metal,
providing (220) at least one second bonding member (12) on the substrate (10) for second bonding the semiconductor optical device (20) to the substrate (10),
bonding (230) the semiconductor optical device (20) to the at least one first bonding member (11),
aligning (240) the optical axis (OAX1) of the semiconductor optical device (20) with the optical axis (OAX2) of the optical circuit (30) by applying force to the semiconductor optical device (20) to deform the at least one first bonding member (11), and
bonding (250) the aligned semiconductor optical device (20) by the at least one second bonding member (12).

13. The method of claim 12, wherein the aligning (240) comprises applying the force by a flip-chip bonder head (40) or arm (40) holding the semiconductor optical device (20) during the active alignment.

14. The method of claim 12, comprising melting the at least one second bonding member (12) in a reflow soldering process.
